(19) United States
(12) Patent Application Publication
(10) Pub. No.: US 2018/0358250 A1
(43) Pub. Date: Dec. 13, 2018

(54) PROCESSING APPARATUS

(71) Applicant: DISCO CORPORATION, Tokyo (JP)

(72) Inventor: Kazuma Sekiya, Tokyo (JP)

(21) Appl. No.: 15/997,275

(22) Filed: Jun. 4, 2018

(30) Foreign Application Priority Data
Jun. 8, 2017 (JP) 2017-113072

(51) Int. Cl. H01L 21/67; H01L 21/677; H01L 21/687

(52) U.S. Cl. CPC H01L 21/67294; H01L 21/67766; H01L 21/68707; H01L 21/67778; H01L 21/67769

(57) ABSTRACT

In a processing apparatus, a delivery unit for delivering a wafer includes a first wafer holding pad detachably coupled to the tip end of a mobile unit, for holding the wafer, and an unloading unit for unloading and loading a wafer includes a second wafer holding pad detachably coupled to the tip end of a mobile unit, for holding the wafer. The processing apparatus also includes a wafer holding pad storage unit for storing a plurality of first and second wafer holding pads available in a plurality of types matching different kinds of wafers. Before the wafer is unloaded from a cassette, the delivery unit and the unloading unit are equipped respectively with the first wafer holding pad and the second wafer holding pad that correspond to the wafer.

### BACKGROUND OF THE INVENTION

### Field of the Invention

The present invention relates to a processing apparatus for processing a wafer.

### Description of the Related Art

Various wafers made of silicon, SiC, sapphire, and so on from which to fabricate various devices such as semiconductor devices, optical devices including light emitting diodes (LEDs), and so on have identification marks in the form of characters or bar codes in the vicinity of a peripheral edge of the face or reverse side of the wafers, for identifying dimensional information about the types of the devices, the thicknesses of the wafers, the intervals between streets on the wafers, etc. and also information about processing conditions, etc.

The identification marks on wafers are read by identification mark reading mechanisms provided in various processing apparatus and used to confirm what types of wafers have been introduced into the processing apparatus (see, for example, Japanese Patent No. 4342861). The identification marks on wafers are available in various different locations on the wafers and in various different kinds depending on products to be fabricated from the wafers. Therefore, it is necessary for the identification mark reading mechanisms provided in processing apparatus to have adjustments made for illumination, etc. so that they can reliably read the identification marks on wafers.

Before shipping manufactured processing apparatus to customers, it is customary for the manufacturers to carry out a mark reading test on the processing apparatus, in which the identification mark readers of the identification mark reading mechanisms provided in the processing apparatus actually read the identification marks on wafers. After having verified the identification mark reading mechanisms, the manufacturers ship the processing apparatus to the customers, so that the delivered processing apparatus will be prevented from causing trouble by failing to read identification marks on wafers.

### SUMMARY OF THE INVENTION

Wafers are held by wafer holding pads while they are being unloaded from cassettes and delivered in processing apparatus which process wafers. There are available a plurality of types of wafer holding pads for holding different kinds of wafers in the processing apparatus. A cluster module system includes an unloading unit for unloading wafers from cassettes and a delivery unit for delivering different types of wafers to be processed. Each time the kind of wafers to be processed is changed, it is necessary to change wafer holding pads on the unloading unit and the delivery unit, and such a changing process is tedious and time-consuming.

It is therefore an object of the present invention to provide a processing apparatus that is capable of simply selecting wafer holding pads suitable for various different kinds of wafers.

In accordance with an aspect of the present invention, there is provided a processing apparatus including a cassette placing unit for placing thereon a cassette that houses a plurality of wafers therein, an unloading unit for unloading a wafer from the cassette placed on the cassette placing unit, a delivery unit for delivering the wafer unloaded by the unloading unit, a plurality of processing/treating units disposed adjacent to the delivery unit, for performing respective different processing or treating processes on the wafer, and a control unit for controlling the cassette placing unit, the unloading unit, the delivery unit, and the processing/treating units. The delivery unit includes a straight guide rail, a mobile unit movably supported on the straight guide rail, and a first wafer holding pad for holding the wafer, the first wafer holding pad being detachably coupled to a tip end of the mobile unit. The unloading unit includes a second wafer holding pad for holding the wafer and a mobile robot for unloading or loading a wafer, the second wafer holding pad being detachably coupled to a tip end of the mobile robot. The processing apparatus further includes a wafer holding pad storage unit for storing a plurality of first wafer holding pads and second wafer holding pads available in a plurality of types matching different kinds of wafers. Before a wafer is unloaded from the cassette, the delivery unit and the unloading unit are equipped respectively with a first wafer holding pad and a second wafer holding pad that correspond to the wafer.

The control unit includes a memory for storing wafer holding pad information about first wafer holding pads and second wafer holding pads that correspond to and match the different kinds of wafers, with respect to each of wafer identifiers (IDs) corresponding to the respective wafers. Before a wafer is unloaded from the cassette, the control unit instructs the delivery unit and the unloading unit to be equipped respectively with a first wafer holding pad and a second wafer holding pad based on the wafer holding pad information stored in the memory. The delivery unit and the unloading unit are equipped respectively with a first wafer holding pad and a second wafer holding pad as instructed by the control unit.

The processing apparatus according to the present invention includes the wafer holding pad storage unit for storing a plurality of first wafer holding pads and second wafer holding pads available in a plurality of types matching different kinds of wafers. Before a wafer is unloaded from the cassette, the delivery unit and the unloading unit are equipped respectively with a first wafer holding pad and a second wafer holding pad that correspond to the wafer. The unloading unit and the delivery unit can deliver various kinds of wafers without the need for a complex process of changing wafer holding pads.

Furthermore, since the memory stores wafer holding pad information about different kinds of wafers with respect to each wafer ID, the delivery unit and the unloading unit can automatically be equipped respectively with first and second wafer holding pads suitable for a wafer based on the wafer holding pad information stored in the memory before the wafer is unloaded from the cassette. Therefore, the processing apparatus can operate with increased efficiency.

According to the present invention, therefore, the processing apparatus is capable of simply selecting wafer holding pads suitable for various different kinds of wafers.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1 is an exploded perspective view of a processing apparatus according to an embodiment of the present invention, with units being illustrated as being separated;

FIG. 2 is a perspective view of the processing apparatus according to the embodiment, with the units being put together;

FIG. 3A is a cross-sectional view depicting the manner in which a wafer holding pad to be replaced is put into a storage compartment;

FIG. 3B is a cross-sectional view depicting the manner in which an unloading unit or a delivery unit is equipped with a wafer holding pad that has replaced another;

FIG. 4 is a perspective view depicting the manner in which a wafer holding pad of one type is disconnected from a connect/disconnect block of an unloading unit or a delivery unit;

FIG. 5 is a perspective view depicting the manner in which a wafer unit is held on the wafer holding pad depicted in FIG. 4 that has been coupled to the connect/disconnect block of the unloading unit or the delivery unit;

FIG. 6 is a perspective view depicting the manner in which a wafer holding pad of another type is disconnected from a connect/disconnect block of an unloading unit or a delivery unit; and

FIG. 7 is a perspective view depicting the manner in which a wafer is held on the wafer holding pad depicted in FIG. 6 that has been connected to the connect/disconnect block of the unloading unit or the delivery unit.

### DETAILED DESCRIPTION OF THE PREFERRED EMBODIMENTS

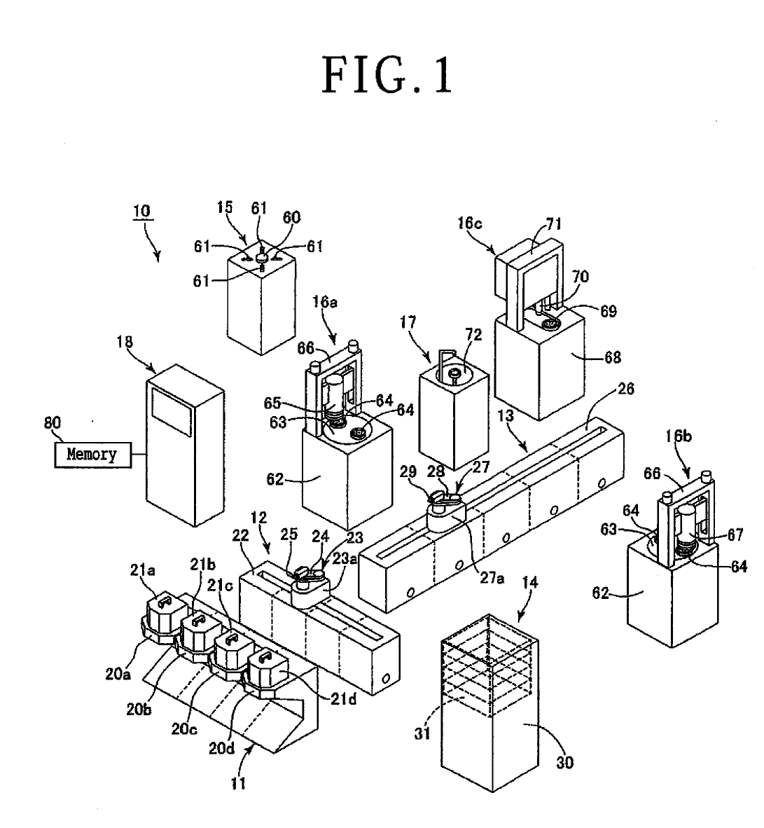

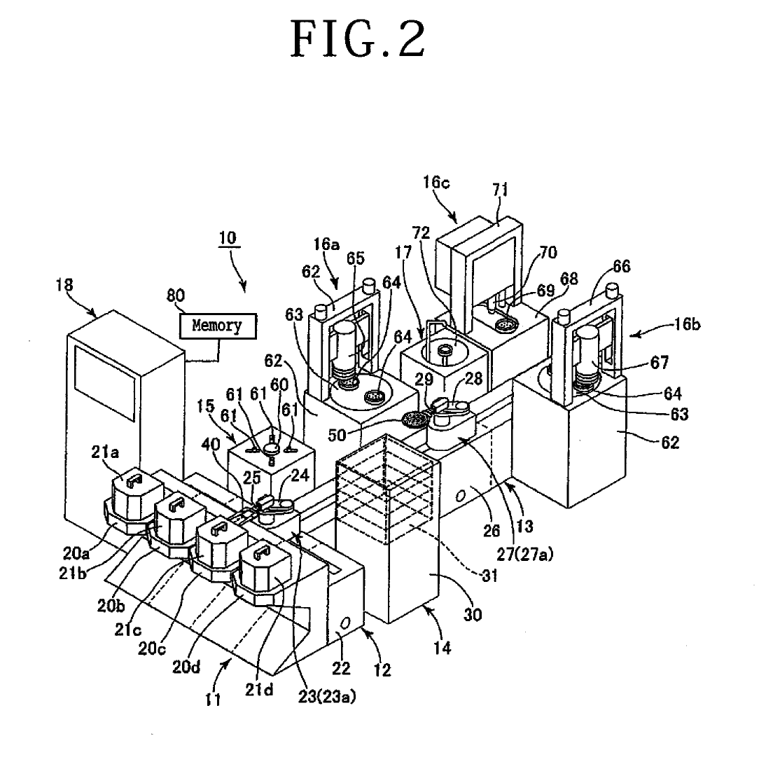

A processing apparatus according to an embodiment of the present invention will hereinafter be described below with reference to the accompanying drawings. The processing apparatus, denoted by 10 and depicted in its entirety in FIGS. 1 and 2, is a cluster module system made up of a plurality of combined units having various different functions. The processing apparatus 10 is capable of processing various kinds of different wafers simultaneously. FIG. 1 depicts the processing apparatus 10 with the units separated from each other, and FIG. 2 depicts the processing apparatus 10 with the units combined together.

The processing apparatus 10 includes a cassette placing unit 11, an unloading unit 12, a delivery unit or transfer unit 13, a wafer holding pad storage unit 14, a centering unit 15, a plurality of processing/treating units 16a, 16b and 16c, a cleaning unit 17, and a control unit 18.

The cassette placing unit 11 includes a plurality of cassette placing tables 20a, 20b, 20c and 20d arranged in a row and a plurality of cassettes 21a, 21b, 21c and 21d placed respectively on the cassette placing tables 20a, 20b, 20c and 20d. Each of the cassettes 21a, 21b, 21c and 21d is able to house a plurality of wafer units 33 or wafers 38 to be described later.

The unloading unit 12 includes a guide rail 22 extending straight along the row of the cassette placing tables 20a, 20b, 20c and 20d of the cassette placing unit 11 and a mobile robot 23 movably supported on the guide rail 22 for movement therealong. The mobile robot 23 includes a base 23a movably supported on the guide rail 22 and a robot arm 24 as a multi-axis articulated robot arm mounted on the base 23a. A connect/disconnect block 25 is mounted on the tip end of the robot arm 24. A plurality of wafer holding pads to be described later can selectively be detachably coupled to the connect/disconnect block 25. The base 23a is movably supported for longitudinal movement along the guide rail 22, and can be moved therealong by drive forces from a linear motor housed in the base 23a.

The delivery unit 13 includes a guide rail 26 extending straight perpendicularly to the longitudinal axis of the guide rail 22 of the unloading unit 12 and mobile means 27 movably supported on the guide rail 26 for movement therealong. The mobile means 27 includes a base 27a movably supported on the guide rail 26 and a robot arm 28 as a multi-axis articulated robot arm mounted on the base 27a. A connect/disconnect block 29 is mounted on the tip end of the robot arm 28. A plurality of wafer holding pads to be described later can selectively be detachably coupled to the connect/disconnect block 29. The base 27a is movably supported for longitudinal movement along the guide rail 26, and can be moved therealong by drive forces from a linear motor housed in the base 27a.

As depicted in FIG. 2, when the units of the processing apparatus 10 are combined together, the wafer holding pad storage unit 14, the centering unit 15, the processing/treating units 16a, 16b and 16c, and the cleaning unit 17 are disposed adjacent to the guide rail 26 of the delivery unit 13. The wafer holding pad storage unit 14 and the centering unit 15 are disposed in respective positions at a longitudinal end of the guide rail 26 that is close to the guide rail 22. The wafer holding pad storage unit 14 and the centering unit 15 can be accessed by both the robot arm 24 of the unloading unit 12 and the robot arm 28 of the delivery unit 13.

When the mobile robot 23 of the unloading unit 12 is actuated, it can unload a wafer that is housed in one of the cassettes 21a, 21b, 21c and 21d and load or put a wafer into one of the cassettes 21a, 21b, 21c and 21d. When the mobile means 27 of the delivery unit 13 is actuated, it can deliver a wafer to one of the processing/treating units 16a, 16b and 16c and the cleaning unit 17. The unloading unit 12 and the delivery unit 13 each can deliver a wafer to the centering unit 15.

While a wafer is being delivered between the units by the unloading unit 12 and the delivery unit 13, the wafer is held by a wafer holding pad. Either one of the wafer holding pads that are available in different types suitable for different kinds of wafers can be detachably coupled to each of the connect/disconnect block 25 of the unloading unit 12 and the connect/disconnect block 29 of the delivery unit 13. The wafer holding pads are stored in the wafer holding pad storage unit 14. When in use, wafer holding pads corresponding to wafers to be processed are selected from the wafer holding pad storage unit 14, and connected to the tip ends of the connect/disconnect blocks 25 and 29. According to the present invention, the wafer holding pad that is connected to the connect/disconnect block 29 of the delivery unit 13 will be referred to as a first wafer holding pad, whereas the wafer holding pad that is connected to the connect/disconnect block 25 of the unloading unit 12 will be referred to as a second wafer holding pad.

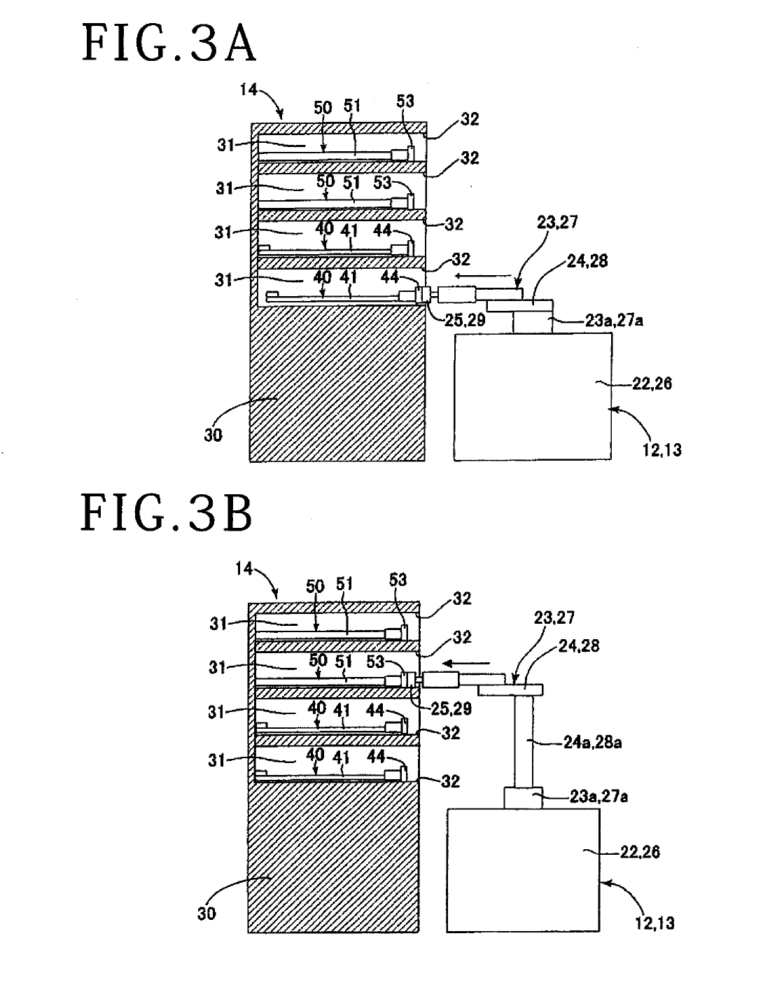

As depicted in FIGS. 3A and 3B, the wafer holding pad storage unit 14 has a casing 30 with a plurality of (four in the embodiment) storage compartments 31 defined therein. The storage compartments 31 are arranged in a vertical row and separated by partitions interposed therebetween. The casing 30 has a plurality of loading/unloading openings 32 defined in a vertical side wall thereof and connected to the respective storage compartments 31.

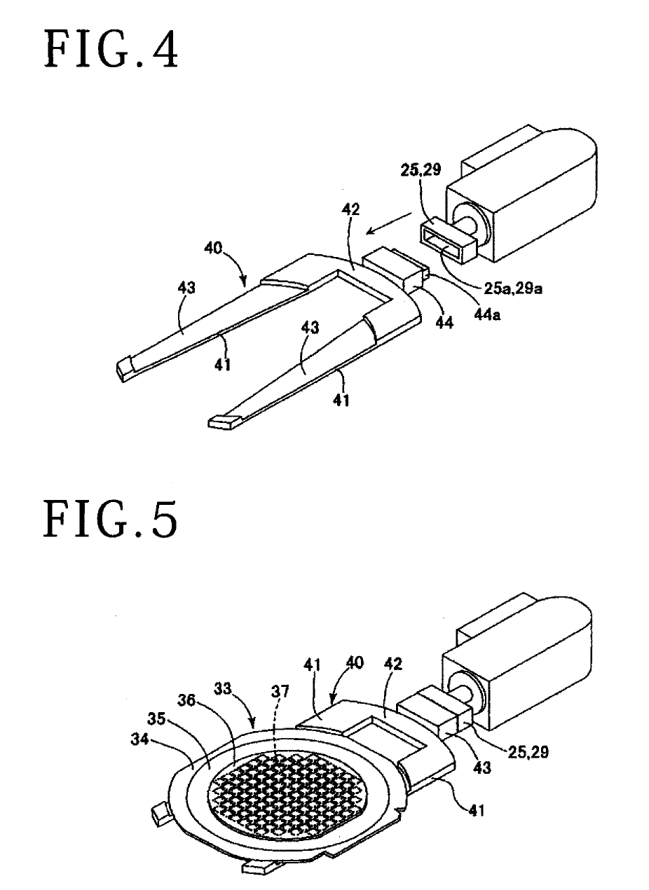

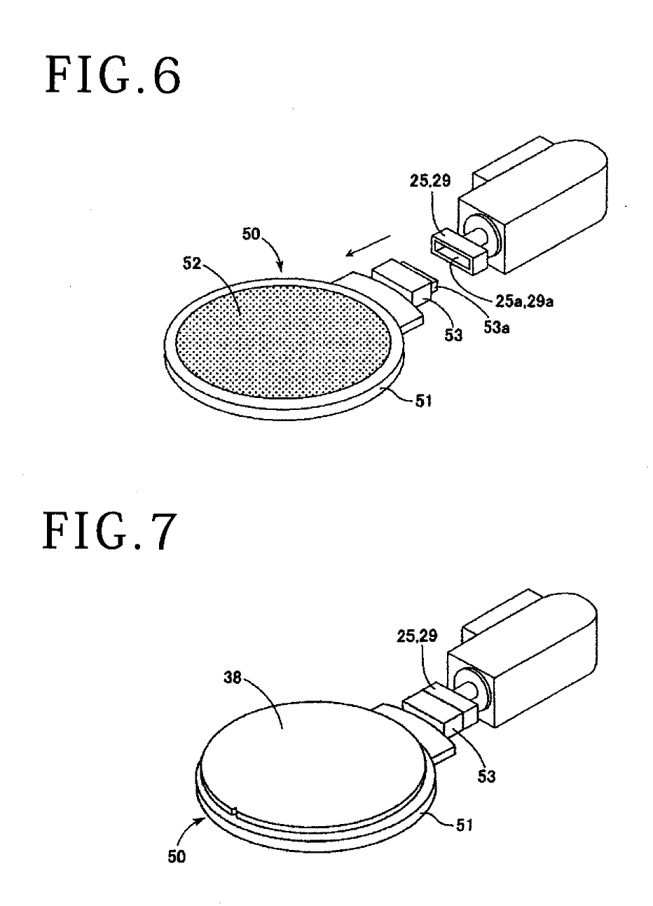

According to the present embodiment, the wafer holding pads available in different types corresponding to kinds of wafers to be processed include by way of example a wafer holding pad 40 (see FIG. 4) suitable for holding a wafer unit 33 (see FIG. 5) and a wafer holding pad 50 (see FIG. 6) suitable for holding a wafer 38 (see FIG. 7). The wafer holding pads are not limited to these two types, but it is possible to use various different types of wafer holding pads depending on conditions such as the kinds, shapes, and the thicknesses of wafers to be held thereby. Three or more kinds of wafer holding pads may be used together.

As depicted in FIG. 5, the wafer unit 33 includes an annular frame 34 with a circular hole defined therein and a wafer 36 stuck to the annular frame 34 over the circular hole with a tape 35 interposed therebetween. The wafer 36 has a face side demarcated into a plurality of rectangular areas by a grid of projected dicing lines and a plurality of devices 37 formed in the respective rectangular areas. The face side of the wafer 36 on which the devices 37 are formed is stuck to an adhesive surface of the tape 35.

As depicted in FIGS. 4 and 5, the wafer holding pad 40 is of a forked shape including a pair of spaced support plates 41 having respective proximal ends interconnected by a joint 42. The support plates 41 jointly have a recess 43 defined in their upper surfaces and shaped to allow the wafer unit 33 to be fitted therein. The annular frame 34 has an outer peripheral shape that is substantially circular and includes a pair of diametrically opposite straight edges. The recess 43 has an inner peripheral shape complementary to the circular outer peripheral shape of the annular frame 34, so that circular part of the annular frame 34 can be neatly fitted in the recess 43. The wafer holding pad 40 also includes a connect/disconnect bracket 44 joined to an end of the joint 42 that is opposite the other end thereof from which the support plates 42 extend.

As depicted in FIGS. 6 and 7, the wafer holding pad 50 includes a disk-shaped base 51 that has an upper surface serving as a suction surface 52. The suction surface 52 is of a circular shape large enough to hold a wafer 38 thereon. The suction surface 52 is made of porous ceramics and capable of holding the wafer 38 under suction thereon by a suction force applied from suction means, not depicted, and acting through the suction surface 52 to the wafer 38. The wafer holding pad 50 also has a connect/disconnect bracket 53 joined to an outer peripheral edge of the base 51.

The connect/disconnect block 25 of the unloading unit 12 and the connect/disconnect block 29 of the delivery unit 13 are each connectable to and disconnectable from the connect/disconnect bracket 44 and the connect/disconnect bracket 53. Specifically, the connect/disconnect brackets 44 and 53 of the wafer holding pads 40 and 50 have a common connect/disconnect structure, and the connect/disconnect block 25 of the unloading unit 12 and the connect/disconnect block 29 of the delivery unit 13 have a common connect/disconnect structure.

These connect/disconnect structures may have any of various structural details. According to the present embodiment, as depicted in FIGS. 4 and 6, the connect/disconnect blocks 25 and 29 have coupling cavities 25a and 29a, respectively, and the connect/disconnect brackets 44 and 53 have coupling protrusions 44a and 53a, respectively, that can be removably inserted into the respective coupling cavities 25a and 29a. When the coupling protrusions 44a and 53a are inserted into the respective coupling cavities 25a and 29a, as depicted in FIGS. 5 and 7, engaging means, not depicted, provided in the respective coupling cavities 25a and 29a and the coupling protrusions 44a and 53a engage each other, keeping the wafer holding pad 40 and the wafer holding pad 50 connected to the connect/disconnect blocks 25 and 29. When the engaging means are disengaged from each other, the wafer holding pad 40 and the wafer holding pad 50 can be disconnected from the connect/disconnect blocks 25 and 29.

One example of the engaging means may be elastically deformable engaging hooks on the coupling protrusions 44a and 53a or in the coupling cavities 25a and 29a, and engaging holes defined in the coupling cavities 25a and 29a or the coupling protrusions 44a and 53a. When the coupling protrusions 44a and 53a start to be inserted into the coupling cavities 25a and 29a, the engaging hooks are elastically deformed. Then, when the coupling protrusions 44a and 53a are inserted into the coupling cavities 25a and 29a by a predetermined distance, the engaging hooks snap back and engage in the engaging holes. Alternatively, the engaging hooks may be moved by actuators, rather than being elastically formed, into and out of engagement with the engaging holes.

The connect/disconnect structures of the connect/disconnect blocks 25 and 29 and the connect/disconnect brackets 44 and 53 may have structural details other than those described above. For example, the connect/disconnect blocks 25 and 29 and the connect/disconnect brackets 44 and 53 may remain connected to each other under magnetic forces or by a mechanical connector other than the engaging hooks and the engaging holes.

If the unloading unit 12 and the delivery unit 13 are each to hold the wafer unit 33 (the wafer 36), as depicted in FIGS. 4 and 5, then each of the wafer holding pads 40 that are stored in the storage compartments 31 in the wafer holding pad storage unit 14 is connected to the connect/disconnect block 25 or 29. Then, the wafer unit 33 is held in the recess 43 in the wafer holding pad 40, as depicted in FIG. 5.

If the unloading unit 12 and the delivery unit 13 are each to hold the wafer 38, as depicted in FIGS. 6 and 7, then each of the wafer holding pads 50 that are stored in the storage compartments 31 in the wafer holding pad storage unit 14 is connected to the connect/disconnect block 25 or 29. Then, the wafer 38 is held on the suction surface 52, as depicted in FIG. 7.

The unloading unit 12 and the delivery unit 13 each have a suction channel, not depicted, defined therein which extends between a suction source, not depicted, and one of the connect/disconnect blocks 25 and 29. The wafer holding pad 50 has a suction channel, not depicted, defined therein which extends from the suction surface 52 to the connect/disconnect bracket 53. When these suction channels are connected to each other, they allow a suction force from the suction source to act on the suction surface 52.

For changing the kind of a wafer to be held, the wafer holding pad that is currently connected to each of the connect/disconnect blocks 25 and 29 is replaced with another wafer holding pad corresponding to the kind of a new wafer to be held. For example, FIGS. 3A and 3B depict the manner in which a wafer holding pad 40 connected to each of the connect/disconnect blocks 25 and 29 is replaced with a wafer holding pad 50.

As depicted in FIGS. 3A and 3B, of the four storage compartments 31 in the wafer holding pad storage unit 14, lower two are set as storage spaces for wafer holding pads 40, and upper two as storage spaces for wafer holding pads 50. In FIG. 3A, a wafer holding pad 40 connected to the connect/disconnect block 25 or 29 which has been taken out of the lowermost one of the four storage compartments 31 is inserted through the loading/unloading opening 32 into the lowermost storage compartment 31. When the inserted wafer holding pad 40 reaches a predetermined position in the storage compartment 31, the connect/disconnect block 25 or 29 is disconnected from the connect/disconnect bracket 44 of the wafer holding pad 40, and then moved back away from the storage compartment 31, leaving the wafer holding pad 40 in the storage compartment 31.

Each of the storage compartments 31 may have a sensor installed therein for detecting whether a wafer holding pad is stored in the storage compartment 31 or not and how a wafer holding pad is inserted into the storage compartment 31. Based on a signal from the sensor, it is possible to detect whether the storage of the wafer holding pad 40 in the storage compartment 31 is completed or not. Therefore, a highly accurate process of storing the wafer holding pad 40 in the storage compartment 31 can be performed.

Thereafter, as depicted in FIG. 3B, the connect/disconnect block 25 or 29 is lifted by a lifting/lowering mechanism 24a or 28a that supports the robot arm 24 or 28, up to the height of one of the storage compartments 31 that stores a wafer holding pad 50 therein. In FIG. 3B, the connect/disconnect block 25 or 29 is illustrated as being lifted to the position of the second highest storage compartment 31. However, the connect/disconnect block 25 or 29 may be lifted to the position of the uppermost storage compartment 31. Then, the connect/disconnect block 25 or 29 is inserted through the loading/unloading opening 32 into the storage compartment 31 and connected to the connect/disconnect bracket 53 of the wafer holding pad 50 stored in the storage compartment 31. The connect/disconnect block 25 or 29 is moved back away from the storage compartment 31, pulling the wafer holding pad 50 out of the storage compartment 31.

As depicted in FIG. 2, the wafer holding pad storage unit 14 is positioned adjacent to both the guide rail 22 of the unloading unit 12 and the guide rail 26 of the delivery unit 13. Both the connect/disconnect block 25 of the unloading unit 12 and the connect/disconnect block 29 of the delivery unit 13 can be connected to the wafer holding pads 40 and the wafer holding pads 50 that are stored in the wafer holding pad storage unit 14. Specifically, providing the casing 30 of the wafer holding pad storage unit 14 has a plurality of loading/unloading openings 32 defined in side walls thereof that face the guide rails 22 and 26, the robot arms 24 and 28 as multi-axis articulated robot arms can operate to cause the connect/disconnect blocks 25 and 29 to reach the storage compartments 31 through the loading/unloading openings 32.

The loading/unloading openings 32 defined in the side walls of the casing 30 that face the guide rails 22 and 26 allow both the unloading unit 12 and the delivery unit 13 to gain access to the storage compartments 31. With the loading/unloading openings 32 defined in those different side walls of the casing 30, the connect/disconnect brackets 44 and 53 in the storage compartments 31 may have different orientations depending on the orientations of the loading/unloading openings 32 through which the wafer holding pads 40 and 50 have passed into the storage compartments 31. Consequently, the processing apparatus 10 may have memory means, e.g., a memory 80 of the control unit 18 to be described later, for storing the orientations of the connect/disconnect brackets 44 and 53 upon storage of the wafer holding pads 40 and 50 in the storage compartments 31, and directions along which the connect/disconnect blocks 25 and 29 are to approach the connect/disconnect brackets 44 and 53 may be selected on the basis of the orientations stored in the memory means. Alternatively, the casing 30 may have turntables disposed in the respective storage compartments 31 for supporting wafer holding pads 40 and 50 thereon, and, after the wafer holding pads 40 and 50 have been stored in the storage compartments 31, the turntables may be turned to align the orientations of all the brackets 44 and 53 in the storage compartments 31.

The wafer holding pads 40 and 50 are connected to the connect/disconnect block 25 of the unloading unit 12 and the connect/disconnect block 29 of the delivery unit 13 before wafers to be processed are unloaded from the cassettes 21a, 21b, 21c and 21d. If wafer units 33 are to be unloaded from the cassettes 21a, 21b, 21c and 21d, then wafer holding pads 40 are connected to the connect/disconnect blocks 25 and 29. If wafers 38 are to be unloaded from the cassettes 21a, 21b, 21c and 21d, then wafer holding pads 50 are connected to the connect/disconnect blocks 25 and 29. In FIG. 2, a wafer holding pad 40 is illustrated as being connected to the connect/disconnect block 25, and a wafer holding pad 50 is illustrated as being connected to the connect/disconnect block 29. The unloading unit 12 and the delivery unit 13 are actuated to deliver a wafer unit 33 and a wafer 38 along predetermined routes to predetermined units of the processing apparatus 10 where they are processed. Routes to be followed and processing details are different depending on conditions including the kinds of wafers to be processed and devices on wafers to be processed. Structural and operational details of the units of the processing apparatus 10 to be described below are by way of example only and applicable to the cluster module system according to the illustrated embodiment. Wafers or wafer units that are delivered may not necessarily be handled by all the units of the processing apparatus 10.

The centering unit 15 includes a placing table 60 for placing a wafer unit 33 or a wafer 38 on its upper surface and four angularly spaced abutments 61 disposed on the placing table 60 and radially movable toward and away from the center of the placing table 60. Each of the abutments 61 is in the form of a cylindrical pin movably disposed in a slot defined in the upper surface of the placing table 60. After a wafer unit 33 or a wafer 38 has been placed on the placing table 60, the abutments 61 are moved radially inwardly toward the center of the placing table 60 and abut against the outer periphery of the wafer unit 33 or the wafer 38, thereby centering the wafer unit 33 or the wafer 38 on the placing table 60. The centering unit 15 centers a wafer unit 33 or a wafer 38 thereon before it is delivered to the processing/treating units 16a, 16b and 16c for processing and after it is processed and returned to the cassettes 21a, 21b, 21c and 21d.

According to the present embodiment, the processing/treating units 16a, 16b and 16c include a rough grinding unit 16a, a finishing grinding unit 16b, and a laser processing unit 16c. The rough grinding unit 16a has a turntable 63 angularly movably supported on a unit housing 62, two chuck tables 64 supported on the turntable 63, rough grinding means 65 positioned above the turntable 63, and support means 66 supporting the rough grinding means 65. The turntable 63 is angularly moved about its own axis to position the two chuck tables 64 alternately in a processing area below the rough grinding means 65 and a wafer loading/unloading area near the guide rail 26 of the delivery unit 13. Each of the two chuck tables 64 is capable of holding a wafer, i.e., a wafer unit 33 or a wafer 38, under suction on its upper surface. The rough grinding means 65, which is vertically movably supported by the support means 66, performs a rough grinding process on a wafer, i.e., a wafer 36 or a wafer 38, on the chuck table 64 below the rough grinding means 65, using grinding stones of the rough grinding means 65. The finishing grinding unit 16b is basically identical in structure to the rough grinding unit 16a except that it includes finishing grinding means 67 rather than the rough grinding means 65. Those parts of the finishing grinding unit 16b which are identical to those of the rough grinding unit 16a are denoted by identical reference symbols, and will not be described below. The finishing grinding unit 16b performs a finishing grinding process on a wafer, i.e., a wafer 36 or a wafer 38, on the chuck table 64 below the finishing grinding means 67, using grinding stones of the finishing grinding means 67.

The laser processing unit 16c includes a chuck table 69 supported on a unit housing 68, laser beam applying means 70 positioned above the chuck table 69, and support means 71 supporting the laser beam applying means 70. The laser beam applying means 70 is movably supported by the support means 71. The chuck table 69 is movable in processing feed directions with respect to the laser beam applying means 70, and is capable of holding a wafer, i.e., a wafer unit 33 or a wafer 38, under suction on its upper surface. The laser processing unit 16c performs a predetermined laser processing sequence on a wafer held on the chuck table 69 with a laser beam that is applied thereto by the laser beam applying means 70.

The cleaning unit 17 includes known spinner-type cleaning means, not depicted, for performing a spinner cleaning process on a wafer that is supplied to a cleaning area 72 in the cleaning unit 17.

The cassette placing unit 11, the unloading unit 12, the delivery unit 13, the centering unit 15, the rough grinding unit 16a, the finishing grinding unit 16b, the laser processing unit 16c, and the cleaning unit 17 described above have respective unit control means for controlling their own operations and working sequences. The control unit 18 exchanges control signals with the unit control means of these units to control the processing apparatus 10 in its entirety.

The control unit 18 has a memory 80 (see FIGS. 1 and 2). The memory 80 stores wafer IDs corresponding to individual wafers handled by the processing apparatus 10 and processing conditions for the wafers. The processing conditions include delivery routes (delivery sequences between the units) for wafers in the processing apparatus 10, processing details, cleaning conditions, and other conditions required from the start to end of processing sequences. Information about wafer holding pads suitable for the respective wafers is stored in advance in the memory 80 for each of the wafer IDs as an element of the processing conditions.

The processing apparatus 10 may include detecting means for automatically detecting the wafer IDs. One example of the detecting means may be optical means for optically reading a two-dimensional image formed on each wafer to acquire a wafer ID from the two-dimensional image. Wafer IDs thus read by the detecting means are sent to and stored in the memory 80. Using the detecting means, it is possible to increase the working efficiency of the processing apparatus 10.

Before an unprocessed wafer, i.e., a wafer unit 33 or a wafer 38, is unloaded from the cassettes 21a, 21b, 21c and 21d, the control unit 18 gives an instruction to connect a wafer holding pad (the wafer holding pad 40 or the wafer holding pad 50 in the present embodiment) based on the wafer IDs and wafer holding pad information stored in the memory 80. According to the instruction, the unloading unit 12 and the delivery unit 13 are operated to connect an appropriate wafer holding pad to the connect/disconnect block 25 or the connect/disconnect block 29. If a wafer holding pad of another kind has already been connected to the connect/disconnect block 25 or the connect/disconnect block 29, the unloading unit 12 and the delivery unit 13 disconnect the connected wafer holding pad, store the disconnected wafer holding pad back in the wafer holding pad storage unit 14, and connect a new wafer holding pad to the connect/disconnect block 25 or the connect/disconnect block 29.

Alternatively, it is possible for the operator who operates the processing apparatus 10 to connect (replace an existing wafer holding pad with) a wafer holding pad corresponding to a wafer to be unloaded from the cassettes 21a, 21b, 21c and 21d. In this case, the operator does not need to perform a complex process as a wafer holding pad is connected and/or disconnected by the unloading unit 12 and the delivery unit 13 once the operator has entered an instruction for them.

In the processing apparatus 10 according to the present embodiment, as described above, wafer holding pads 40 and 50 available in a plurality of types which can be connected to and disconnected from the connect/disconnect blocks 25 and 29 are stored in the wafer holding pad storage unit 14 that is incorporated as part of the cluster module system, and wafer holding pads that match the kind of wafers to be delivered are connected to the respective connect/disconnect blocks 25 and 29. Accordingly, wafer holding pads that match the kinds of various wafers can simply be selected and used, eliminating the complexities of a process of changing wafer holding pads.

In particular, manpower required for selecting and connecting wafer holding pads can be greatly economized by automatically selecting and connecting wafer holding pads that match wafers based on the wafer IDs and wafer holding pad information stored in the memory 80 of the control unit 18.

In the above embodiment, the two types of wafer holding pads, i.e., the wafer holding pad 40 and the wafer holding pad 50, are stored in the wafer holding pad storage unit 14. However, wafer holding pads are not limited to the illustrated types and structures. Wafer holding pads available in a plurality of types that are similar to the wafer holding pad 40 except that the recess 43 has different sizes and depths may be employed, and wafer holding pads available in a plurality of types that are similar to the wafer holding pad 50 except that the suction surface 52 has different diameters. The present invention is not limited to wafer holding pads for holding wafers or wafer units from below, like the wafer holding pads 40 and 50, but is also applicable to wafer holding pads for holding wafers or wafer units by applying a suction force from above, e.g., wafer holding pads for attracting wafers based on the Bernoulli effect. It is possible to use three or more types of wafer holding pads rather than two types of wafer holding pads.

While the wafer holding pad storage unit 14 has four storage compartments 31 and hence stores four wafer holding pads in the illustrated embodiment, it may have more or less spaces for storing wafer holding pads or may store more or less wafer holding pads.

The delivery unit 13 according to the above embodiment has only one mobile means 27. However, the present invention is also applicable to a processing apparatus including a multi-stage delivery unit having a plurality of mobile means.

The processing/treating units in the processing apparatus are not limited to the rough grinding unit 16a, the finishing grinding unit 16b, and the laser processing unit 16c, but may further include various other unit for performing different processing or treating processes such as a cutting process, a polishing process, a plasma etching process, an edge trimming process, a breaking process, an ablating process, and so on.

The processing apparatus according to the present invention is applicable to a wide variety of kinds of wafers (workpieces), e.g., a semiconductor device wafer, an optical device wafer, a package board, a semiconductor board, an inorganic material board, an oxide wafer, a raw ceramic board, and a piezoelectric board, etc. The semiconductor device wafer may include a silicon wafer or a compound semiconductor wafer with devices formed thereon. The optical device wafer may include a sapphire wafer or a silicon carbide wafer with devices formed thereon. The package board may include a chip size package (CSP) board. The semiconductor board may include a board made of silicon, gallium arsenide, or the like. The inorganic material board may include a board made of sapphire, ceramics, glass, or the like. The oxide wafer may include a wafer made of lithium tantalate, lithium niobate, or the like with or without devices formed thereon.

The present invention is not limited to the embodiment and modifications described above, but many changes, replacements, and modifications may be made without departing from the scope of the present invention. Furthermore, the present invention may be reduced to practice according to other techniques, processes, schemes, plans, or arrangements insofar as they are capable of implementing the principles of the present invention owing to technological advances or derivations. Therefore, the scope of the appended claims should be interpreted as covering all the embodiments falling within the range of the technical idea of the present invention.

As described above, the present invention is advantageous in that wafer holding pads which match various kinds of wafers can simply be selected in a processing apparatus for processing a plurality of kinds of wafers, and is useful when applied to a processing apparatus that is required to increase productivity and reduce working burdens.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A processing apparatus comprising:
a cassette placing unit for placing thereon a cassette that houses a plurality of wafers therein;
an unloading unit for unloading a wafer from the cassette placed on the cassette placing unit;
a delivery unit for delivering the wafer unloaded by the unloading unit;
a plurality of processing/treating units disposed adjacent to the delivery unit, for performing respective different processing or treating processes on the wafer; and
a control unit for controlling the cassette placing unit, the unloading unit, the delivery unit, and the processing/treating units,
wherein the delivery unit includes a straight guide rail, a mobile unit movably supported on the straight guide rail, and a first wafer holding pad for holding the wafer, the first wafer holding pad being detachably coupled to a tip end of the mobile unit,
the unloading unit includes a second wafer holding pad for holding the wafer and a mobile robot for unloading or loading a wafer, the second wafer holding pad being detachably coupled to a tip end of the mobile robot,
the processing apparatus further includes a wafer holding pad storage unit for storing a plurality of first wafer holding pads and second wafer holding pads available in a plurality of types matching different kinds of wafers, and
before the wafer is unloaded from the cassette, the delivery unit and the unloading unit are equipped respectively with the first wafer holding pad and the second wafer holding pad which correspond to the wafer.

2. The processing apparatus according to claim 1,
wherein the control unit includes a memory for storing wafer holding pad information about first wafer holding pads and second wafer holding pads that correspond to and match the different kinds of wafers, with respect to each of wafer identifiers corresponding to the respective wafers,
before the wafer is unloaded from the cassette, the control unit instructs the delivery unit and the unloading unit to be equipped respectively with the first wafer holding pad and the second wafer holding pad based on the wafer holding pad information stored in the memory, and
the delivery unit and the unloading unit are equipped respectively with the first wafer holding pad and the second wafer holding pad as instructed by the control unit.
